(19) United States
(12) Patent Application Publication
(10) Pub. No.: US 2023/0221641 A1
(43) Pub. Date: Jul. 13, 2023

(54) HARDMASK COMPOSITION, HARDMASK LAYER, AND METHOD OF FORMING PATTERNS

(71) Applicant: SAMSUNG SDI CO., LTD., Yongin-si (KR)

(72) Inventors: Seung-Wook SHIN, Suwon-si (KR); Yushin PARK, Suwon-si (KR); Seunghyun KIM, Suwon-si (KR); Sangchol PARK, Suwon-si (KR); Sangmi KIM, Suwon-si (KR); Seil CHOI, Suwon-si (KR); Huiseon CHOE, Suwon-si (KR)

(21) Appl. No.: 17/969,931

(22) Filed: Oct. 20, 2022

(30) Foreign Application Priority Data
Jan. 11, 2022 (KR) 10-2022-0004200

(51) Int. Cl. G03F 7/09; G03F 7/00; G03F 7/20; G03F 7/40

(52) U.S. Cl. CPC G03F 7/09; G03F 7/0035; G03F 7/20; G03F 7/40

(57) ABSTRACT

A hardmask composition, a hardmask layer manufactured from the hardmask composition, and a method of forming patterns from the hardmask composition, the composition including a solvent; and a polymer including a structural unit represented by Chemical Formula 1,

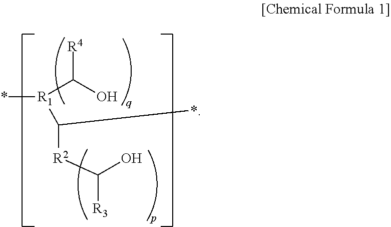

### CROSS-REFERENCE TO RELATED APPLICATION

This application claims priority to and the benefit of Korean Patent Application No. 10-2022-0004200 filed in the Korean Intellectual Property Office on Jan. 11, 2022, the entire contents of which are incorporated herein by reference.

### BACKGROUND

### 1. Field

Embodiments relate to a hardmask composition, a hardmask layer, and a method of forming patterns.

### 2. Description of the Related Art

Recently, the semiconductor industry has developed to an ultra-fine technique having a pattern of several to several tens nanometer size. Such ultrafine technique may use effective lithographic techniques. Some lithographic techniques may include providing a material layer on a semiconductor substrate; coating a photoresist layer thereon; exposing and developing the same to provide a photoresist pattern; and etching a material layer using the photoresist pattern as a mask.

### SUMMARY

The embodiments may be realized by providing a hardmask composition including a solvent; and a polymer including a structural unit represented by Chemical Formula 1,

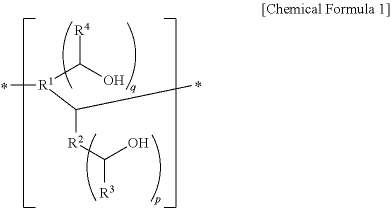

wherein, in Chemical Formula 1, R¹ is a substituted or unsubstituted moiety of Group 1, R² is a substituted or unsubstituted C10 to C30 aromatic hydrocarbon ring group or a substituted or unsubstituted C2 to C30 heteroaromatic hydrocarbon ring group, R³ and R⁴ are each independently a substituted or unsubstituted C6 to C30 aromatic hydrocarbon ring group, at least one of R¹ to R⁴ is substituted with a hydroxyl group, p and q are each independently 0 or 1, and * is a linking point,

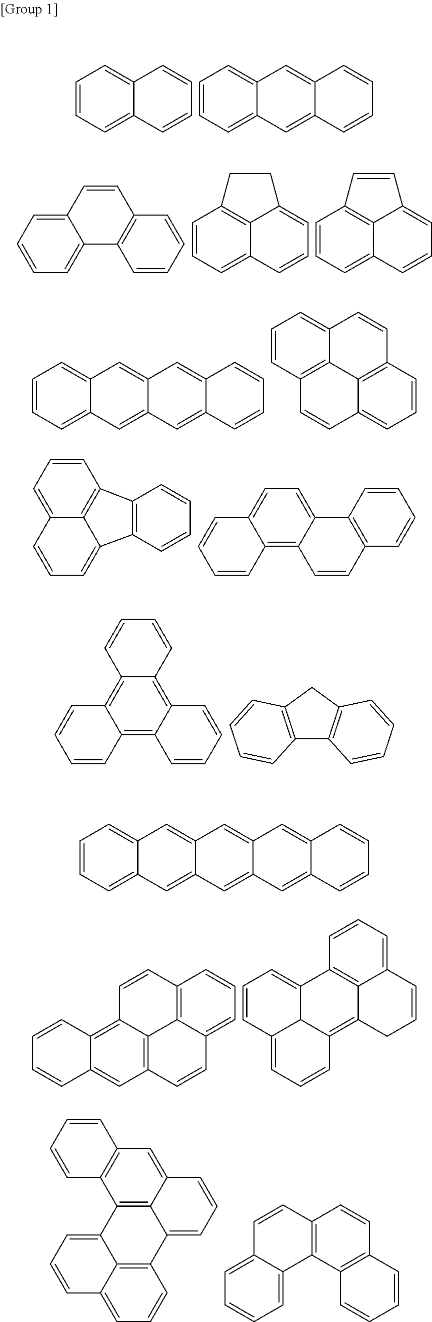

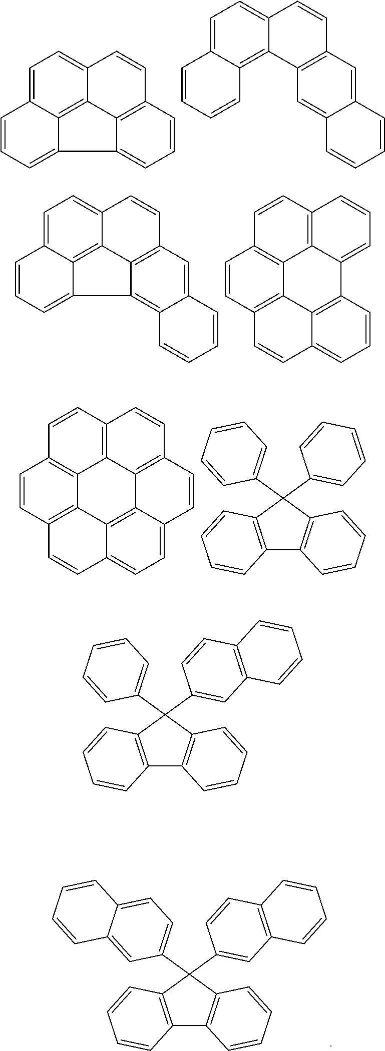

The embodiments may be realized by providing a hardmask layer comprising a cured product of the hardmask composition according to an embodiment.

The embodiments may be realized by providing a method of forming patterns, the method including providing a material layer on a substrate, applying the hardmask composition according to an embodiment on the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a portion of the material layer, and etching an exposed part of the material layer.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not an exclusive term, e.g., “A or B” would include A, B, or A and B.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring. For example, the substituted C6 to C30 aryl group may be fused with another adjacent substituted C6 to C30 aryl group to form a substituted or unsubstituted fluorene ring.

As used herein, when a definition is not otherwise provided, “aromatic hydrocarbon ring group” means a group having one or more hydrocarbon aromatic moieties, and includes a form in which hydrocarbon aromatic moieties are linked by a single bond, a non-aromatic fused ring form in which hydrocarbon aromatic moieties are fused directly or indirectly, or a combination thereof as well as non-condensed aromatic hydrocarbon rings, condensed aromatic hydrocarbon rings.

More specifically, the substituted or unsubstituted aromatic hydrocarbon ring group is a substituted or unsubstituted phenyl group (phenylene group), a substituted or unsubstituted naphthyl group (naphthylene group), a substituted or unsubstituted anthracenyl group (anthracenylene group), a substituted or unsubstituted phenanthryl group (phenanthrylene group), a substituted or unsubstituted naphthacenyl group (naphthacenylene group), a substituted or unsubstituted pyrenyl group (pyrenylene group), a substituted or unsubstituted biphenyl group (biphenylene group), a substituted or unsubstituted terphenyl group (terphenylene group), a substituted or unsubstituted quaterphenyl group (quaterphenylene group), a substituted or unsubstituted chrysenyl group (chrysenylene group), a substituted or unsubstituted triphenylenyl group (triphenylenylene group), a substituted or unsubstituted perylenyl group (perylenylene group), a substituted or unsubstituted indenyl group (indenylene group), a combination thereof, or a combined fused ring of the foregoing groups, but is not limited thereto.

Also, as used herein, the polymer may include both an oligomer and a polymer.

As used herein, when specific definition is not otherwise provided, “weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

There is a constant trend in the semiconductor industry to reduce a size of chips. In order to cope with this demand, a line width of a resist may be patterned to have several tens of nanometers through lithography. Accordingly, a height of the resist may be limited to support the line width of the resist pattern, but the resist may have insufficient resistance in the etching process. In order to compensate for this, an auxiliary layer, which is called a hardmask layer, may be used between a material layer for etching and a photoresist layer. This hardmask layer may serve as an interlayer transferring a fine pattern of the photoresist to the material layer through selective etching and thus is required to have etch resistance, so that it may endure an etching process required for the pattern transfer.

One type of hardmask layer may be formed in a chemical or physical deposition method, and may have low economic efficiency due to a large-scale equipment and a high process cost. Therefore, a method of forming a hard mask layer by a spin-coating technique has recently been developed. The spin-coating technique may be easier to process than other methods and in addition, may help secure excellent gap-fill characteristics and planarization characteristics of a hardmask layer formed therefrom but may tend to slightly deteriorate etch resistance required of the hardmask layer.

Accordingly, a hardmask composition may be used to apply to the spin-coating technique and to secure equivalent etch resistance to that of the hardmask layer formed in the chemical or physical deposit method. Accordingly, in order to improve the etch resistance of a hardmask layer, research on maximizing a carbon content of the hardmask composition is being actively made.

One or more embodiments may provide a hardmask composition capable of not deteriorating etch resistance of a hardmask, while applying the spin-coating technique. As a result, the etch resistance of the hardmask layer formed of the hardmask composition according to an embodiment may be improved by increasing a carbon content of a polymer. In addition, a functional group may also be included in the polymer to help improve crosslinking properties of the hardmask composition according to an embodiment, thereby improving mechanical stability, thermal stability, and chemical resistance of the hardmask layer formed therefrom.

A hardmask composition according to an embodiment may include, e.g., a solvent, and a polymer including a structural unit represented by Chemical Formula 1.

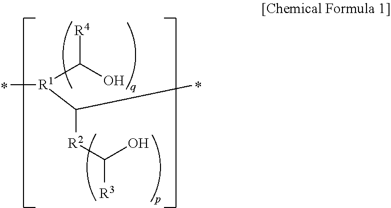

In Chemical Formula 1, R¹ may be or may include, e.g., a substituted or unsubstituted moiety of Group 1.

R² may be or may include, e.g., a substituted or unsubstituted C10 to C30 aromatic hydrocarbon ring group or a substituted or unsubstituted C2 to C30 heteroaromatic hydrocarbon ring group.

R³ and R⁴ may each independently be or include, e.g., a substituted or unsubstituted C6 to C30 aromatic hydrocarbon ring group.

In an implementation, at least one of R¹ to R⁴ may be substituted with, e.g., a hydroxyl group.

p and q may each independently be, e.g., 0 or 1.

* is a linking point:

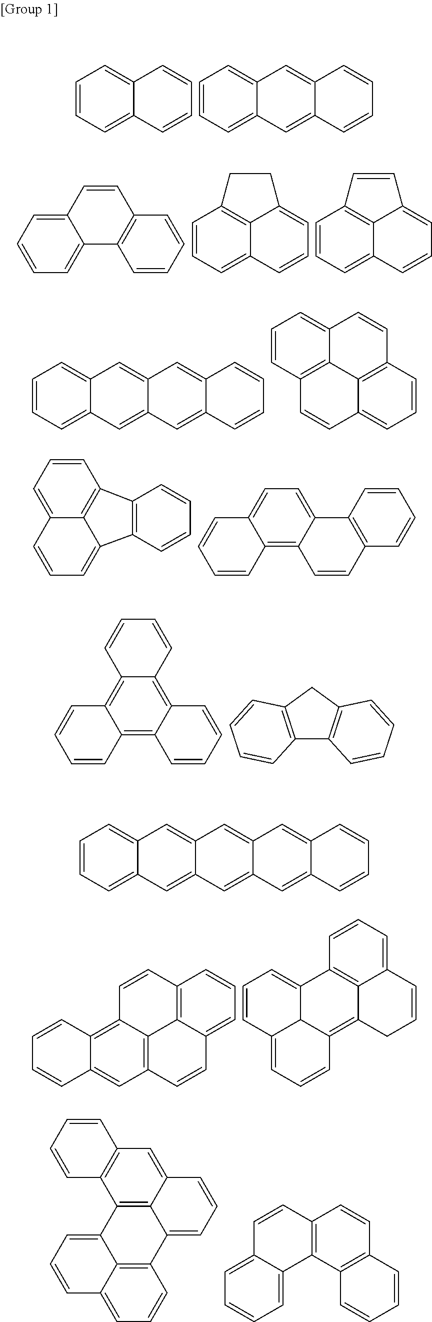

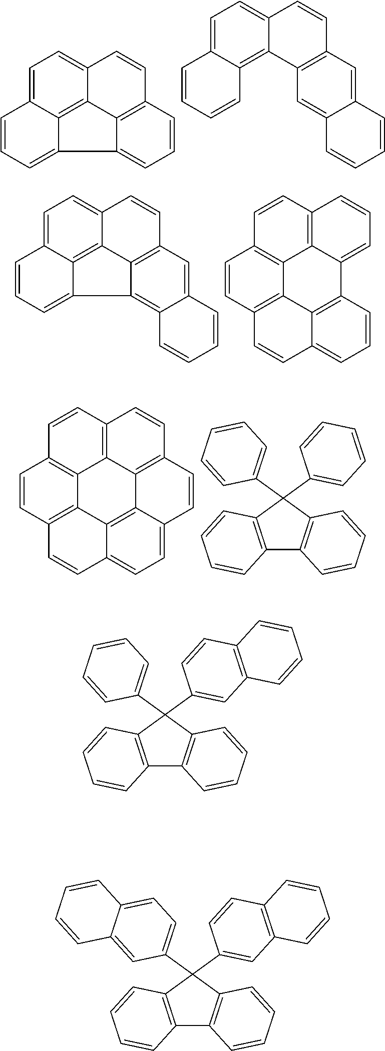

As used herein, a substituted or unsubstituted moiety, e.g., of Group 1, indicates that the moiety may be unsubstituted, as illustrated, or may include an unillustrated substituent thereon

As described above, the polymer included in the composition according to an embodiment may include an aromatic hydrocarbon ring group in both a main chain and a side chain. In an implementation, R¹ and R² may each independently be, e.g., an aromatic hydrocarbon ring group having about 10 or more carbons. Accordingly, when the carbon content is greatly increased in the polymer including the structural unit, a hardmask layer formed of a hardmask composition including the polymer may have high etch resistance.

In addition, the structural unit represented by Chemical Formula 1 may include a hydroxy group, at least one of R¹ to R⁴ may be additionally substituted with a hydroxy group, and the polymer including the structural unit may exhibit excellent crosslinking capability. Accordingly, the composition including the polymer may form another polymer having a higher molecular weight than the polymer included in the initial composition within a short time during, e.g., heat-treatment. Accordingly, a hardmask layer formed from the composition may have excellent mechanical stability, thermal stability, and chemical resistance.

In an implementation, R¹ may be, e.g., a substituted or unsubstituted form of a moiety of Group 1-1.

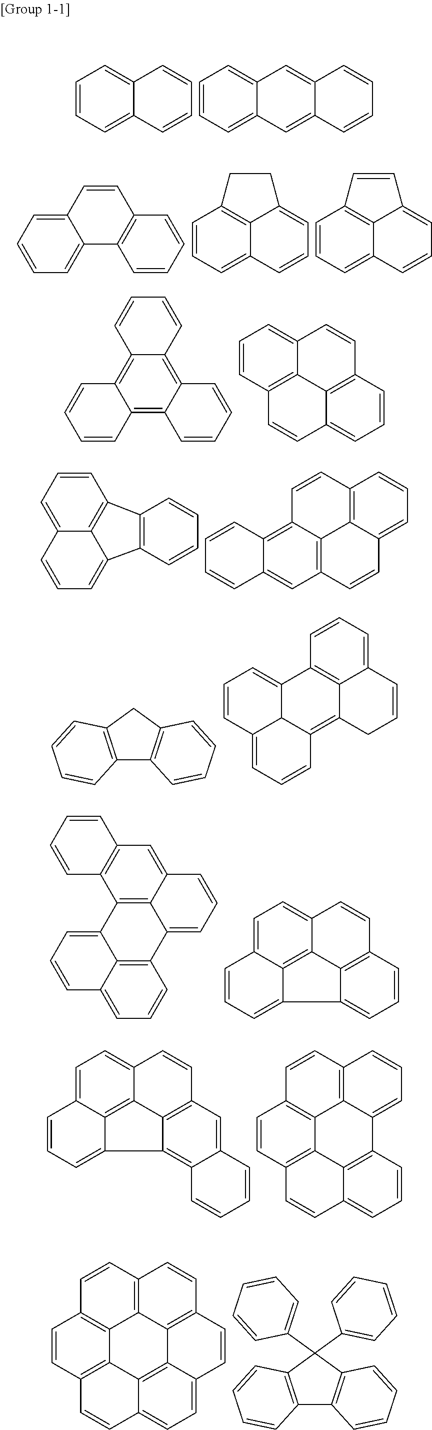

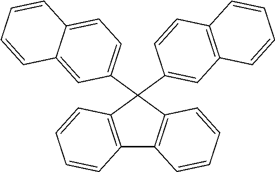 [SMILES: c1ccc2c(c1)-c1ccccc1C2(c1ccc2ccccc2c1)c1ccc2ccccc2c1]

In an implementation, R² may be, e.g., a substituted or unsubstituted C10 to C30 aromatic hydrocarbon ring group. In an implementation, R² may be, e.g., a C10 to C24, a C10 to C20, or a C10 to C16 aromatic hydrocarbon ring group. In an implementation, in R², the substituted or unsubstituted aromatic hydrocarbon ring group may include, e.g., a substituted or unsubstituted moiety of Group 2. In an implementation, in R², the substituted or unsubstituted aromatic hydrocarbon ring group may include, e.g., a substituted or unsubstituted moiety of Group 2-1. In an implementation, R² may include, e.g., a pyrene moiety, a benzopyrene moiety, a perylene moiety, a benzoperylene moiety, or a coronene moiety.

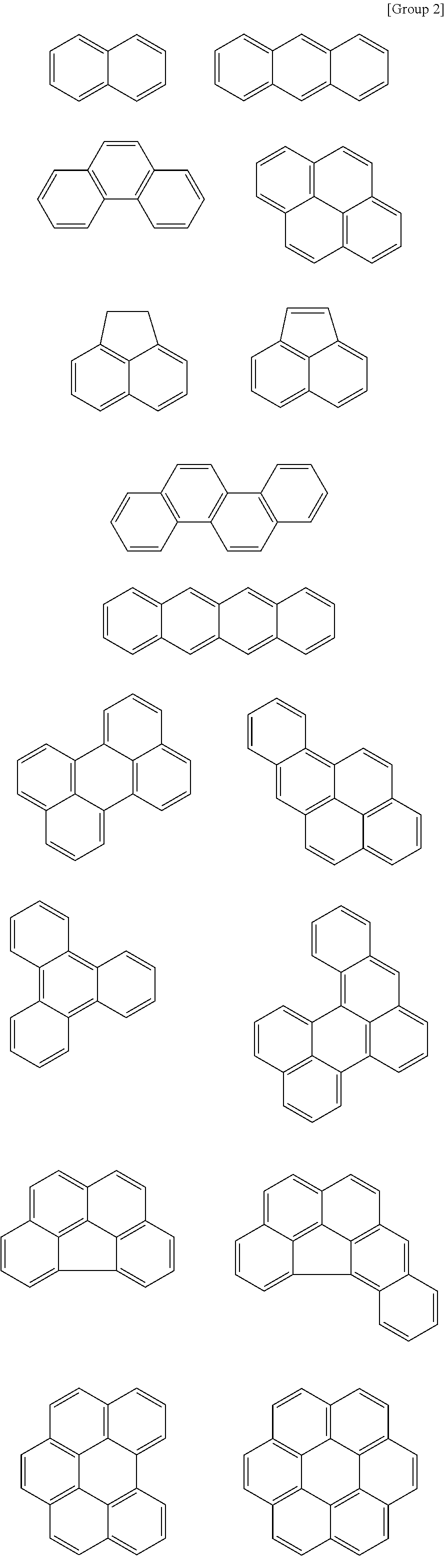

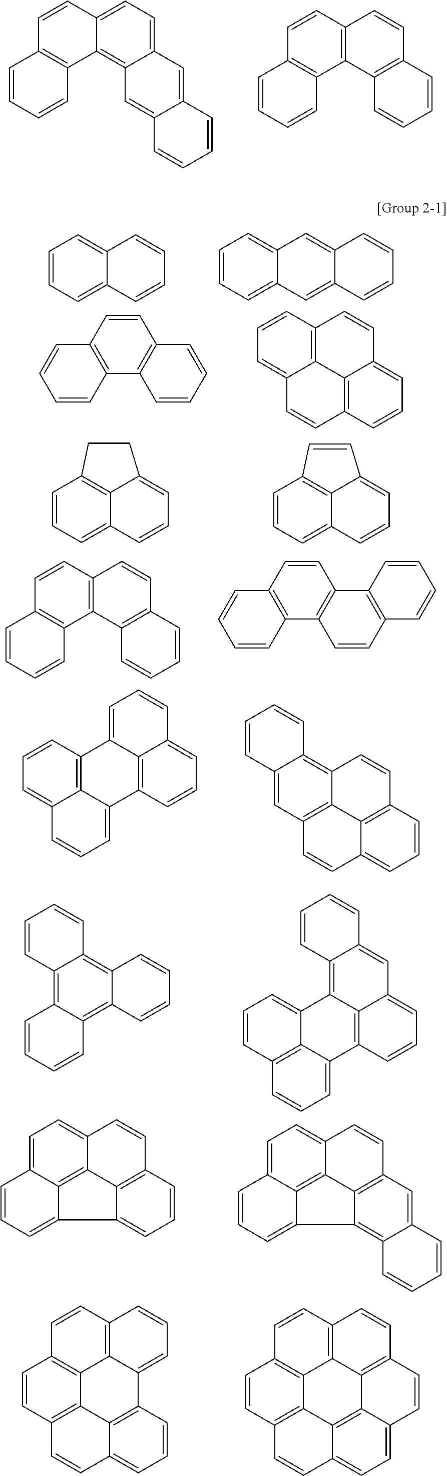

In an implementation, R² may be, e.g., a substituted or unsubstituted C2 to C30 heteroaromatic hydrocarbon ring group. In an implementation, R² may be, e.g., a C6 to C24, C8 to C24, or C10 to C20 heteroaromatic hydrocarbon ring group.

In an implementation, R³ and R⁴ may each independently be, e.g., a substituted or unsubstituted C6 to C30 aromatic hydrocarbon ring group. In an implementation, R³ and R⁴ may each independently be, e.g., a C6 to C24, C6 to C20, or C6 to C16 aromatic hydrocarbon ring group. In an implementation, in R³ and R⁴, the substituted or unsubstituted aromatic hydrocarbon ring group may include, e.g., a moiety of Group 3. In an implementation, in R³ and R⁴, the substituted or unsubstituted aromatic hydrocarbon ring group may include, e.g., a phenyl group, a naphthalene group, or a pyrene group.

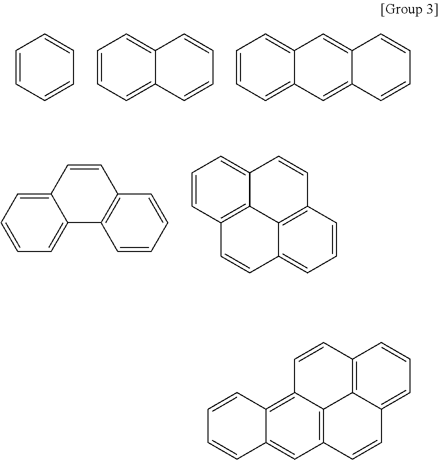

In an implementation, in Chemical Formula 1, R¹ may be, e.g., a substituted or unsubstituted moiety of Group 1-2, R² may be, e.g., a substituted or unsubstituted moiety of Group 2-2, and R³ and R⁴ may each independently be, e.g., a substituted or unsubstituted C6 to C24 aromatic hydrocarbon ring group. In an implementation, at least one of R¹ to R⁴ may be substituted with a hydroxy group.

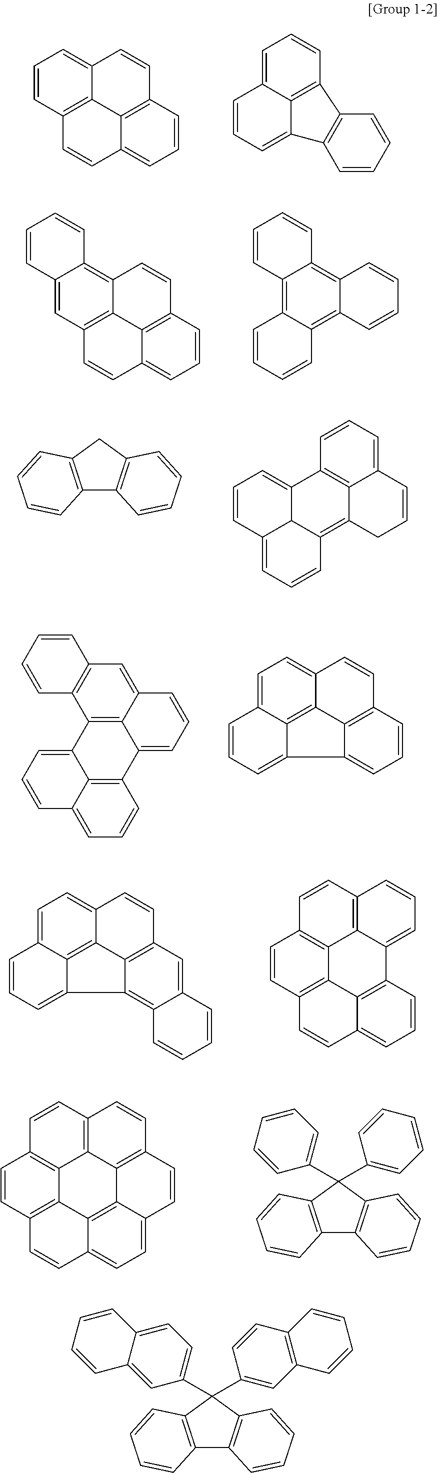

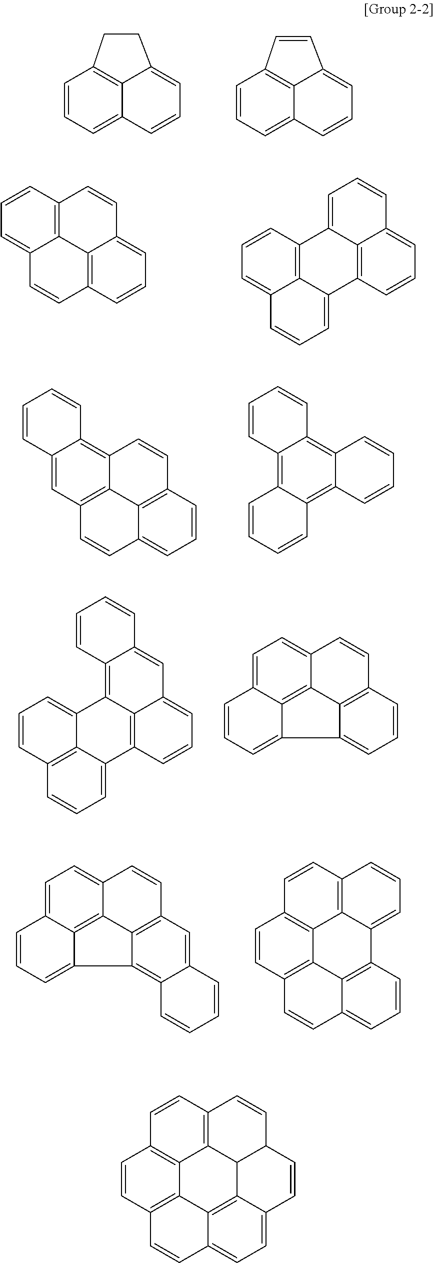

In an implementation, R¹ may include, e.g., a moiety of Group 1-2 that is substituted with one hydroxyl group, and R² may include, e.g., a moiety of Group 2-2 that is substituted with one hydroxyl group.

In an implementation, the structural unit represented by Chemical Formula 1 may be represented by, e.g., Chemical Formula 2.

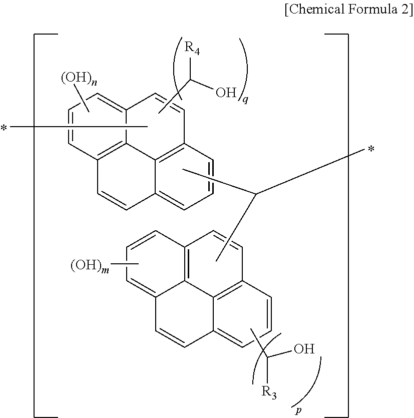

In Chemical Formula 2, R³ and R⁴ may each independently be, e.g., a substituted or unsubstituted C6 to C30 aromatic hydrocarbon ring group. p and q may each independently be, e.g., 0 or 1. n and m may each independently be, e.g., an integer of 0 to 8. In an implementation, when both R³ and R⁴ are unsubstituted C6 to C30 aromatic hydrocarbon ring groups, n+m is not 0.

In an implementation, n and m may each independently be, e.g., an integer of 0 to 7, an integer of 0 to 4, or an integer of 1 to 3. When R³ is an unsubstituted aromatic hydrocarbon ring group, n+m may be, e.g., an integer of 1 or more, an integer of 1 to 10, an integer of 1 to 7, or an integer of 1 to 3.

In an implementation, the structural unit Chemical Formula 1 may be represented by, e.g., one of Chemical Formula 1-1 to Chemical Formula 1-8.

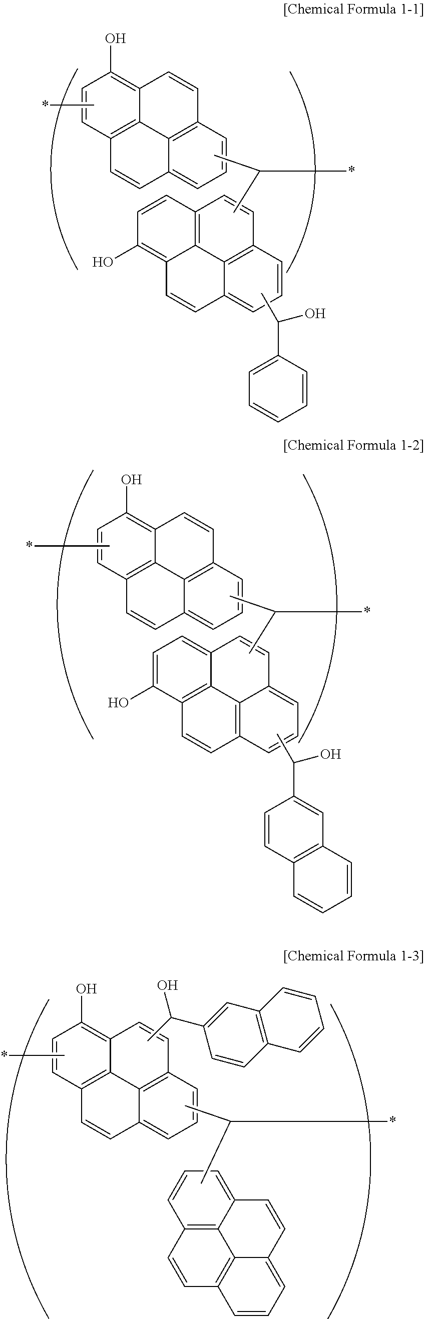

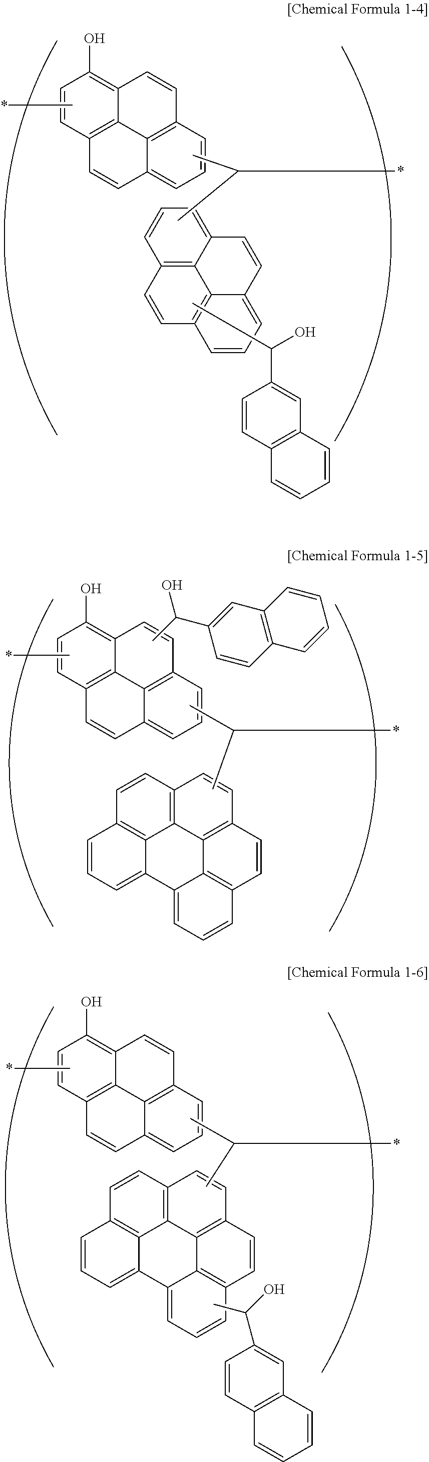

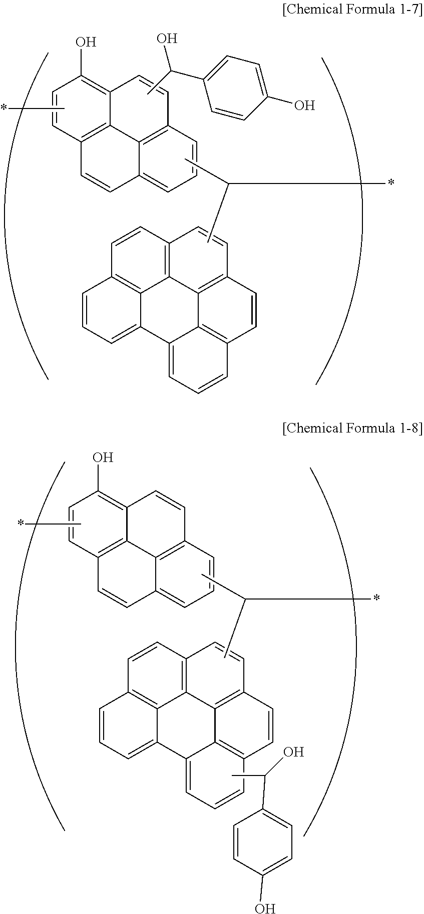

In an implementation, the polymer may have a weight average molecular weight of, e.g., about 1,000 g/mol to about 200,000 g/mol. In an implementation, the polymer may have a weight average molecular weight of, e.g., about 1,000 g/mol to about 150,000 g/mol, about 1,000 g/mol to about 100,000 g/mol, about 1,200 g/mol to about 50,000 g/mol, or about 1,200 g/mol to about 10,000 g/mol. By having a weight average molecular weight in the above ranges, the carbon content and solubility in a solvent of the hardmask composition including the polymer may be adjusted and optimized.

The polymer may be included in an amount of, e.g., about 0.1 wt % to about 30 wt %, based on a total weight of the hardmask composition. In an implementation, the polymer may be included in an amount of, e.g., about 0.2 wt % to about 30 wt %, about 0.5 wt % to about 30 wt %, about 1 wt % to about 30 wt %, about 1.5 wt % to about 25 wt %, or about 2 wt % to about 20 wt %. By including the polymer within the above ranges, a thickness, a surface roughness, and a planarization degree of the hardmask may be easily adjusted.

The hardmask composition according to an embodiment may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. The solvent may be a suitable solvent that has sufficient solubility or dispersibility for the polymer.

In an implementation, the hardmask composition may further include an additive, e.g., a surfactant, a crosslinking agent, a thermal acid generator, or a plasticizer.

The surfactant may include, e.g., a fluoroalkyl-based compound, an alkylbenzenesulfonate, an alkylpyridinium salt, polyethylene glycol, a quaternary ammonium salt, or the like.

The thermal acid generator may include, e.g., an acid compound, for example p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid and/or 2,4,4,6-tetrabromocyclohexadienone, benzointosylate, 2-nitrobenzyltosylate, or other organic sulfonic acid alkyl esters.

According to another embodiment, a hardmask layer including a cured product of the aforementioned hardmask composition may be provided.

Hereinafter, a method of forming patterns using the aforementioned hardmask composition is described.

A method of forming patterns according to an embodiment may include, e.g., providing a material layer on a substrate, applying a hardmask composition including the aforementioned polymer and solvent on the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a portion of the material layer, and etching the exposed portion of the material layer. The substrate may be, e.g., a silicon wafer, a glass substrate, or a polymer substrate.

The material layer may be a material to be finally patterned, e.g., a metal layer such as an aluminum layer and a copper layer, a semiconductor layer such as a silicon layer, or an insulation layer such as a silicon oxide layer or a silicon nitride layer. The material layer may be formed through a method such as a chemical vapor deposition (CVD) process.

The hardmask composition is the same as described above, and may be applied by spin-on coating in a form of a solution. In an implementation, a thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process and a second heat-treating process.

In an implementation, the heat-treating of the hardmask composition may include, e.g., one heat-treating process performed at about 100° C. to about 1,000° C. for about 10 seconds to about 1 hour, and, e.g., the heat-treating may be performed under an atmosphere of air or nitrogen, or an atmosphere having oxygen concentration of 1 wt % or less.

In an implementation, the heat-treating of the hardmask composition may include a first heat-treating process performed, e.g., at about 100° C. to about 1,000° C., about 100° C. to about 800° C., about 100° C. to about 500° C., or about 100° C. to about 400° C. for about 10 seconds to about 1 hour, and a second heat-treating process performed, e.g., at about 100° C. to about 1,000° C., about 300° C. to about 1,000° C., about 500° C. to about 1,000° C., or about 500° C. to about 800° C. for about 10 seconds to about 1 hour consecutively. In an implementation, the first and second heat-treating processes may be performed under an atmosphere of air or nitrogen, or an atmosphere having oxygen concentration of 1 wt % or less.

By performing at least one of the steps of heat-treating the hardmask composition at a high temperature, e.g., of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include a first heat-treating process, a second heat-treating process, a UV/Vis curing process, or a near IR curing process, or may include two or more processes consecutively.

In an implementation, the method may further include forming a silicon-containing thin layer on the hardmask layer. The silicon-containing thin layer may be formed of, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed portion of the material layer may be performed through a dry etching process using an etching gas and the etching gas may include, e.g., N₂/O₂, CHF₃, CF₄, Cl₂, BCl₃, or a mixed gas thereof.

The etched material layer may be formed in a plurality of pattern, and the plurality of pattern may be a metal pattern, a semiconductor pattern, an insulation pattern, or the like, e.g., diverse patterns of a semiconductor integrated circuit device.

Hereinafter, the present disclosure is illustrated in more detail with reference to examples. However, these examples are exemplary, and the present disclosure is not limited thereto.

### EXAMPLES

Polymer Synthesis

### Polymerization Example 1

23.2 g of 1-methoxypyrene, 19.1 g of 2-naphthoylchloride, and 500 g of dichloroethane were put in a 2 L 3-necked flask and stirred with a magnetic bar at ambient temperature for 1 hour, and then, 20 g of trichloroaluminum was little by little added thereto. Subsequently, the mixture was stirred for a reaction for 10 hours. When the reaction was completed, after removing the trichloroaluminum by using water, the residue was dried, obtaining a compound represented by Chemical Formula 1-2a.

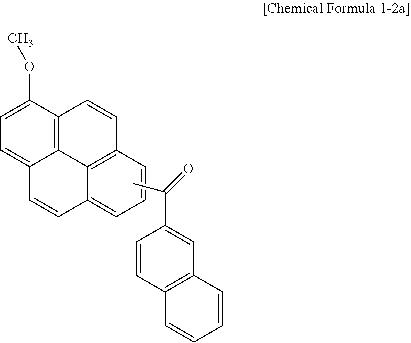

37 g of the compound represented by Chemical Formula 1-2a, 200 g of DMF, and 31 g of phosphoryl chloride were put in a 2 L 3-necked flask and stirred with a magnetic bar for a reaction at 100° C. for 10 hours. When the reaction was completed, the resultant was washed with water and dried. Subsequently, 16 g of the compound, 7 g of potassium hydroxide, and 20 g dodecanethiol were put in a 500 ml 3-necked flask equipped with a thermometer, a condenser, and a mechanical agitator, and 60 g of DMF was added thereto and then, stirred at 100° C. for 12 hours. When a reaction was completed, the resultant was cooled, neutralized to a pH of about 6 with a 7% HCl solution, treated with ethyl acetate to remove a reaction by-product, and distilled, obtaining a compound represented by Chemical Formula 1-2b.

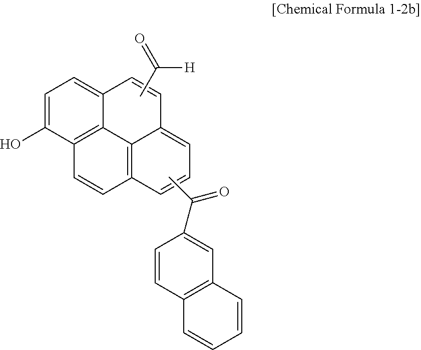

20 g of the compound represented by Chemical Formula 1-2b, 11 g of 1-hydroxypyrene, and 4.8 g of p-toluenesulfonic acid monohydrate were put in a 2 L 3-necked flask and dissolved in 100 g of 1,4-dioxane to prepare a solution, and the solution was stirred using a thermostat to keep a temperature within 90 to ° C. 100° C. to perform a reaction for 20 hours. When the polymerization reaction was completed, the reaction product was slowly cooled to ambient temperature. The reaction product was added to 100 g of distilled water and 1,000 g of methanol and then, vigorously stirred and allowed to stand. After removing a supernatant, precipitates therefrom were dissolved in 300 g of propylene glycol monomethyl ether acetate (PGMEA) and then, vigorously stirred by using 3,200 g of methanol and allowed to stand. Subsequently, 8 g of sodium borohydride was little by little added to the obtained polymer and then, reacted for 12 hours under a mixture of tetrahydrofuran/methanol. When the reaction was completed, a mixture of water/methanol was used to remove a reaction byproduct, obtaining a polymer including a structural unit represented by Chemical Formula 1-2. (Mw: 2,300 g/mol)

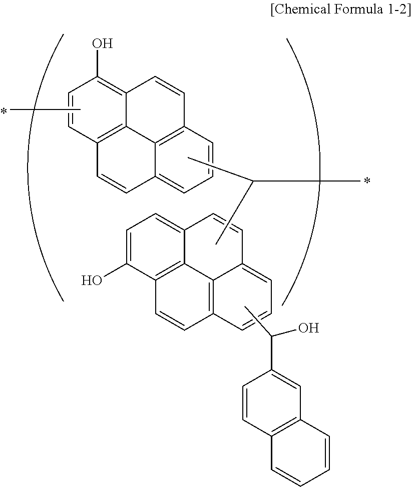

### Polymerization Example 2

23 g of 1-methoxypyrene, 23 g of 1-pyrenecarboxaldehyde, and 19 g of p-toluenesulfonic acid monohydrate were put in a 500 ml 2-necked flask equipped with a mechanical stirrer and a cooling tube and mixed well with 50 g of 1,4-dioxane and then, heated to 105° C. and stirred for 24 hours. After completing a reaction, the temperature was reduced to 60° C. to 70° C., and 300 g of tetrahydrofuran was added thereto to keep a compound not hardened, and a pH of the compound was adjusted to be 5 to 6 by using a 7% sodium bicarbonate aqueous solution. After pouring 1,000 ml of ethyl acetate thereinto and then, continuously stirring the mixture, an organic layer was extracted therefrom by using a separatory funnel. After adding 500 ml of water to the separatory funnel, the separatory funnel was repetitively shaken three times or more to remove acid and sodium salt remaining there, finally extracting an organic layer. Subsequently, the organic solution was concentrated with an evaporator, and 200 g of tetrahydrofuran was added to a polymer obtained therefrom, obtaining a solution. The solution was stirred and slowly added in a dropwise fashion to a beaker containing 5 L of hexane to from precipitates, and the precipitates were filtered, obtaining a polymer (Mw: 1,700 g/mol).

23.2 g of the obtained polymer, 19.1 g of 2-naphthoylchloride, and 500 g of dichloroethane were put in a 2 L 3-necked flask and stirred with a magnetic bar at ambient temperature for 1 hour, and 20 g of trichloroaluminum was little by little added thereto. The mixture was stirred for 10 hours to perform a reaction. When the reaction was completed, after removing the trichloroaluminum by using water, the residue was dried, obtaining a polymer including a structural unit represented by Chemical Formula 2-1a, a structural unit represented by Chemical Formula 2-2a, or a combination thereof.

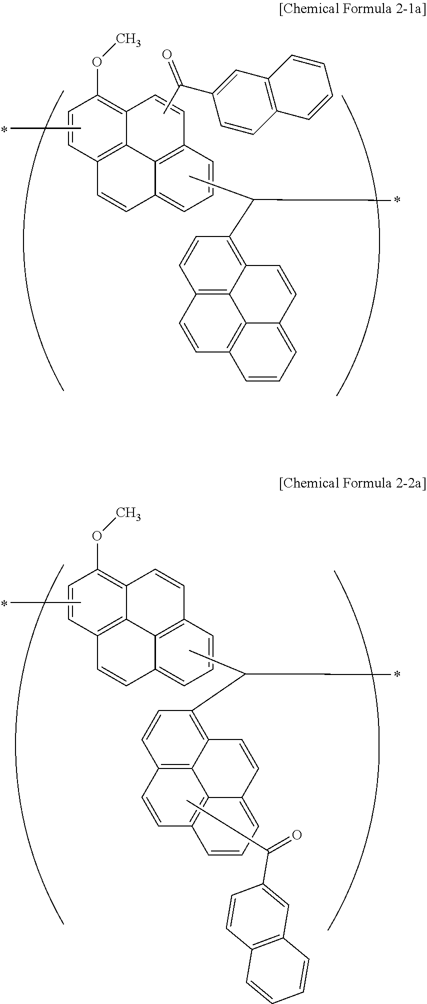

Subsequently, 30 g of the obtained polymer, 7 g of potassium hydroxide, and 20 g of dodecanethiol were put in a 500 ml 3-necked flask equipped with a thermometer, a condenser, and a mechanical agitator, and 250 g of dimethylformamide was added thereto and then, stirred at 100° C. for 12 hours. When a reaction was completed, the resultant was cooled, neutralized to a pH of about 6 by using a 7% HCl solution, and treated with ethyl acetate to remove a reaction by-product. Subsequently, the obtained organic solution was concentrated with an evaporator, and 200 g of tetrahydrofuran was added to a polymer obtained therefrom, obtaining a solution. The solution was slowly added in a dropwise fashion to a beaker containing 5 L of hexane, while stirred, to form precipitates, and the precipitates were filtered and dried, obtaining a powder-type polymer.

16 g of sodium borohydride was little by little added to a mixture of the polymer, tetrahydrofuran, and methanol and then, reacted at 50° C. for 12 hours. When a reaction was completed, a mixture of water/methanol was used to remove a reaction byproduct, obtaining a polymer including a structural unit represented by Chemical Formula 2-1, a structural unit represented by Chemical Formula 2-2, or a combination thereof (Mw: 2,300 g/mol)

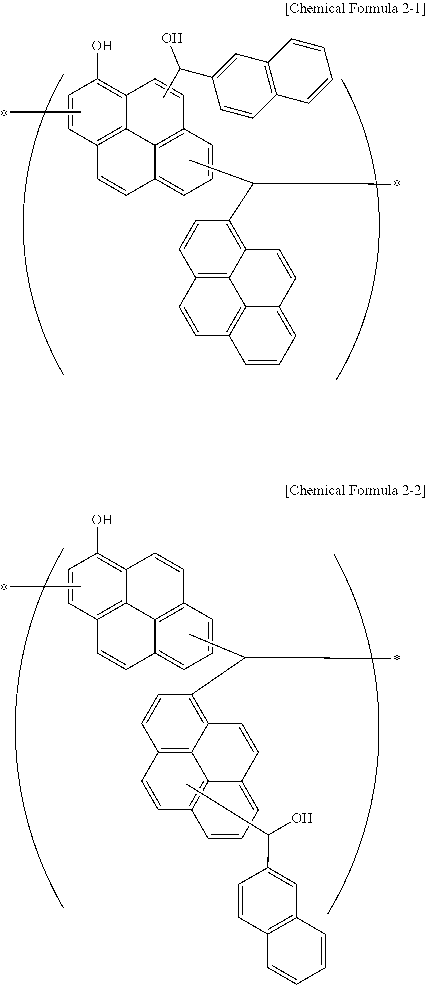

### Polymerization Example 3

A polymer including a structural unit represented by Chemical Formula 3-1, a structural unit represented by Chemical Formula 3-2, or a combination thereof was prepared in the same manner as in Polymerization Example 2 except that 30 g of 1-benzoperylenecarboxaldehyde was used instead of 23 g of the 1-pyrenecarboxaldehyde. (Mw: 1,600 g/mol)

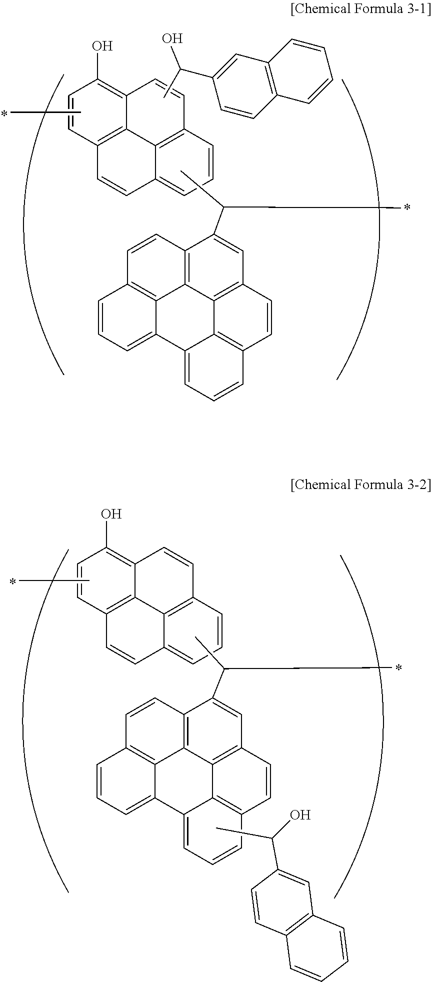

### Polymerization Example 4

A polymer including a structural unit represented by Chemical Formula 4-1a, a structural unit represented by Chemical Formula 4-2a, or a combination thereof was prepared in the same manner as in Polymerization Example 3 except that 19 g of 4-methoxybenzoylchloride was used instead of 19.1 g of the 2-naphthoylchloride.

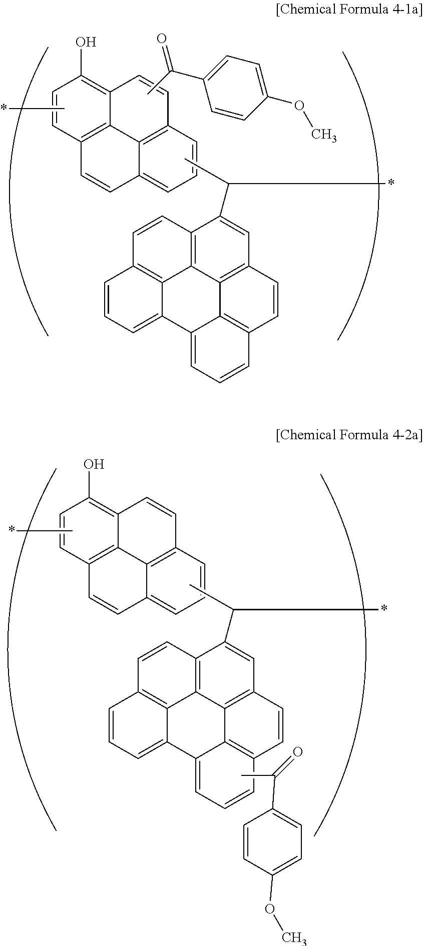

Subsequently, 30 g of the obtained polymer, 7 g of potassium hydroxide, and 20 g of dodecanethiol were put in a 500 ml 3-neck flask equipped with a thermometer, a condenser, and a mechanical agitator, and 200 g of dimethylformamide was added thereto and then, stirred at 100° C. for 12 hours. When a reaction was completed, the resultant was cooled, neutralized to a pH of about 6 by using a 7% hydrogen chloride solution, and treated with ethyl acetate to remove a reaction by-product, and subsequently, an organic solution therefrom was concentrated with an evaporator to obtain a compound, and 200 g of tetrahydrofuran was added to the compound, obtaining a solution. The solution was slowly added in a dropwise fashion to a beaker containing 5 L of hexane, while being stirred, to form precipitates, and the precipitates were filtered and dried, obtaining a powder-type polymer.

15 g of sodium borohydride was little by little added to a mixture of the obtained polymer, tetrahydrofuran, and methanol and then, reacted at 50° C. for 12 hours. When a reaction was completed, the resultant was treated with a mixture of water/methanol to remove a reaction byproduct, obtaining a polymer including a structural unit represented by Chemical Formula 4-1, a structural unit represented by Chemical Formula 4-2, or a combination thereof. (Mw: 2,300 g/mol)

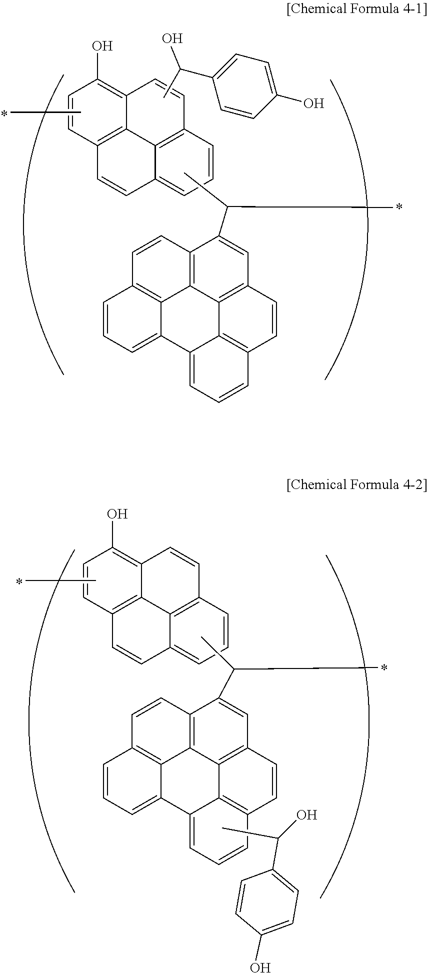

### Comparative Polymerization Example 1

21 g of 1-hydroxypyrene, 23 g of 1-pyrenecarboxaldehyde, and 9.5 g of p-toluenesulfonic acid monohydrate were put with 50 g of 1,4-dioxane in a 500 ml 2-necked flask equipped with a mechanical agitator and a cooling tube and then, heated to 100° C. and stirred for 24 hours. When a reaction was completed, after reducing the internal temperature to about 60° C. to 70° C., 300 g of tetrahydrofuran was thereto to keep a compound not hardened, and a pH of the compound was adjusted to be about 5 to 6 by using a 7% sodium bicarbonate aqueous solution. Subsequently, 1,000 ml of ethyl acetate was poured thereinto and then, continuously stirred, and an organic layer was extracted therefrom by using a separatory funnel. Then, 500 ml of water was added again to the separatory funnel and then, repetitively shaken three times or more to remove acid and sodium salt remaining there, finally extracting an organic layer. Subsequently, the organic solution was concentrated with an evaporator, and 1 L of tetrahydrofuran was added to a compound obtained therefrom, obtaining a solution. The solution was slowly added in a dropwise fashion to a beaker containing 5 L of hexane, while being stirred, to form precipitates, obtaining a polymer including a structural unit represented by Chemical Formula 5. (Mw: 1,500 g/mol)

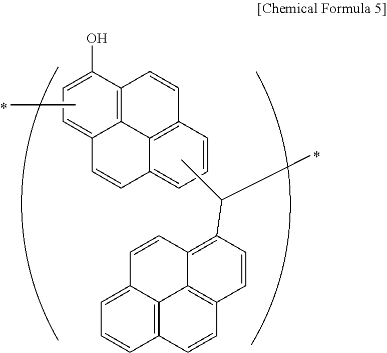

### Example 1

5 g of the compound according to Polymerization Example 1 was stirred with 50 g of a mixture of cyclohexanone:propylene glycolmonomethyl ether acetate (mixed in a volume ratio of 1:1) for 60 minutes and then, filtered with a 0.45 μm TEFLON (tetrafluoroethylene) filter, preparing a hardmask composition.

### Example 2

A hardmask composition was prepared in the same manner as in Example 1 except that the compound of Polymerization Example 2 was used instead of the compound of Polymerization Example 1.

### Example 3

A hardmask composition was prepared in the same manner as in Example 1 except that the compound of Polymerization Example 3 was used instead of the compound of Polymerization Example 1.

### Example 4

A hardmask composition was prepared in the same manner as in Example 1 except that the compound of Polymerization Example 4 was used instead of the compound of Polymerization Example 1.

### Comparative Example 1

A hardmask composition was prepared in the same manner as in Example 1 except that the compound of Comparative Polymerization Example 1 was used instead of the compound of Polymerization Example 1.

Evaluation: Crosslinking Properties

An SC1 solution was prepared by mixing ammonia, hydrogen peroxide, and water in a volume ratio of 1:1:5. Each hardmask composition according to Examples 1 to 4 and Comparative Example 1 was coated on a silicon wafer and then, heat-treated at 400° C. for 2 minutes, forming 200 nm-thick films. The obtained Si substrates were dipped in the SC1 solution heated at 60° C. for 5 minutes and then, measured with respect to a film thickness, which was used to calculate a film loss rate (%).

TABLE 1

| | Film loss rate (%) |
|---|---|
| | after immersion in SC1 solution |
| Example 1 | 3% |
| Example 2 | 5% |
| Example 3 | 5% |
| Example 4 | 3% |
| Comparative Example 1 | 100% |

Referring to Table 1, the organic films formed of the hardmask compositions according to the Examples exhibited a smaller film loss rate than the organic film formed of the hardmask composition according to the Comparative Example. In addition, the hardmask compositions according to the Examples exhibited improved crosslinking properties, and the organic films formed thereof exhibited excellent chemical resistance.

By way of summation and review, according to small-sizing the pattern to be formed, it may be difficult to provide a fine pattern having an excellent profile by using some lithographic techniques. Accordingly, an auxiliary layer, called a hardmask layer, may be formed between the material layer and the photoresist layer to provide a fine pattern.

One or more embodiments may provide a hardmask composition that is effectively applicable to a hardmask layer.

The hardmask composition according to the embodiment may have excellent crosslinking properties, and the hardmask layer formed therefrom may help secure excellent etch resistance and chemical resistance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a solvent; and
a polymer including a structural unit represented by Chemical Formula 1, 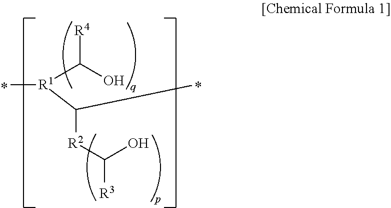
wherein, in Chemical Formula 1,
R¹ is a substituted or unsubstituted moiety of Group 1,
R² is a substituted or unsubstituted C10 to C30 aromatic hydrocarbon ring group or a substituted or unsubstituted C2 to C30 heteroaromatic hydrocarbon ring group,
R³ and R⁴ are each independently a substituted or unsubstituted C6 to C30 aromatic hydrocarbon ring group,
at least one of R¹ to R⁴ is substituted with a hydroxyl group,
p and q are each independently 0 or 1, and
* is a linking point,

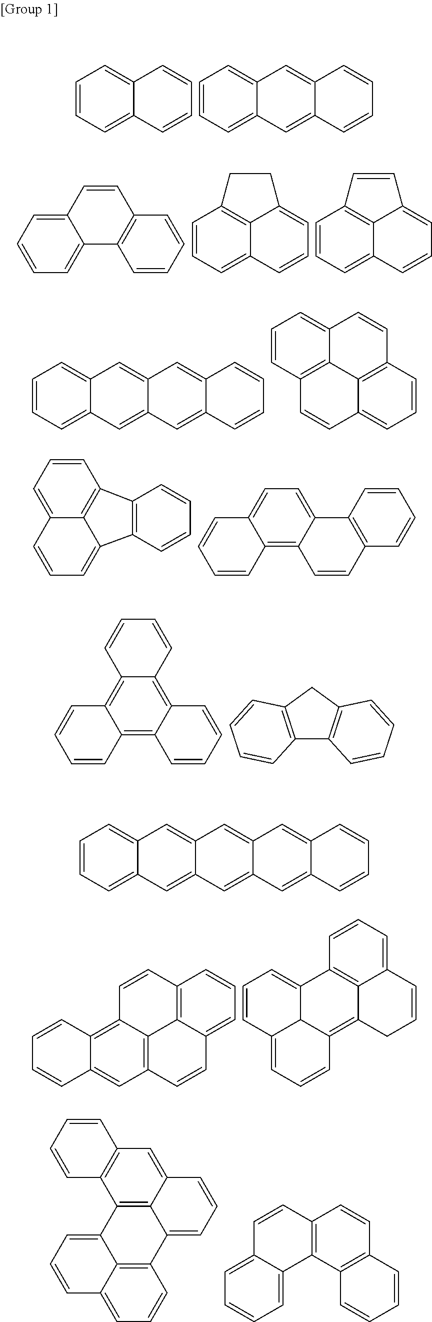

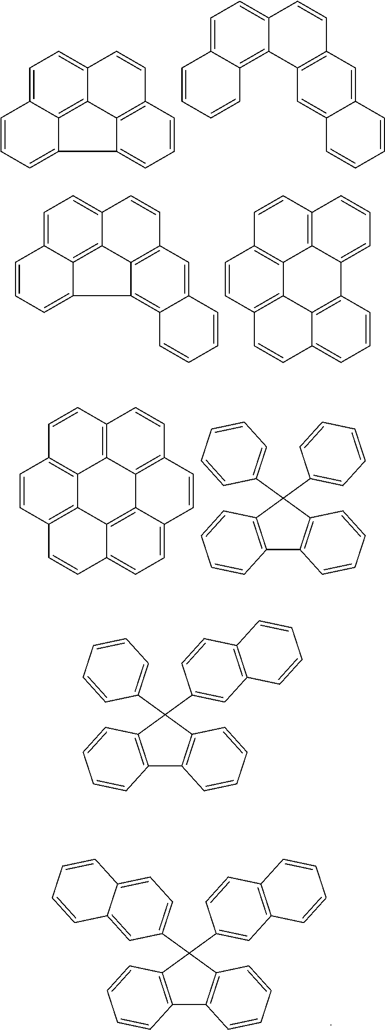

2. The hardmask composition as claimed in claim 1, wherein R¹ is a substituted or unsubstituted moiety of Group 1-1:

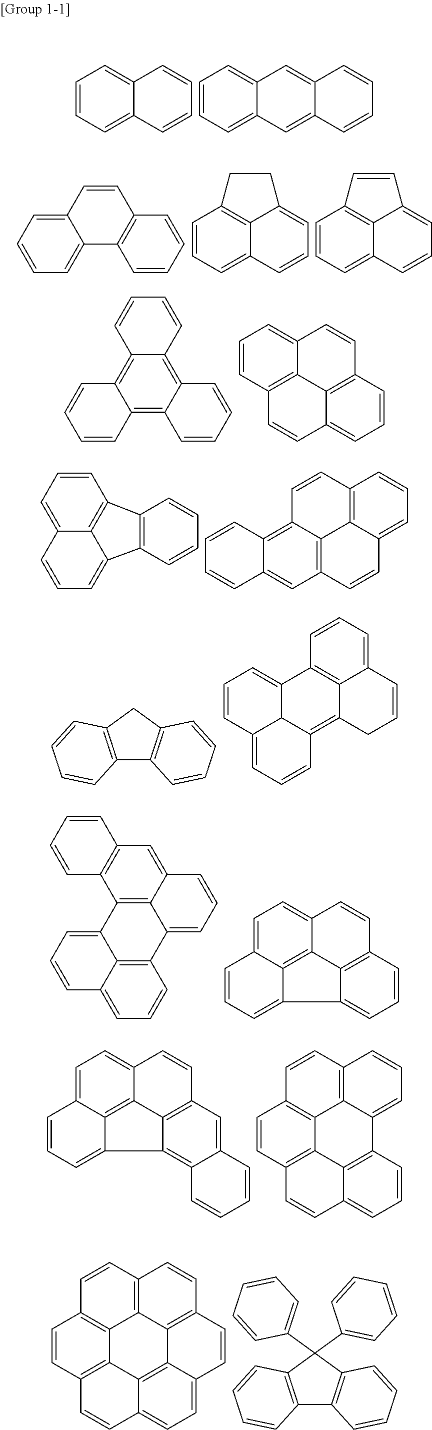

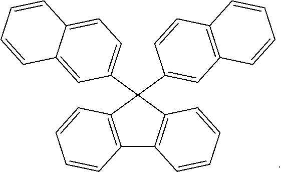 [SMILES: c1ccc2c(c1)-c1ccccc1C2(c1ccc2ccccc2c1)c1ccc2ccccc2c1]

3. The hardmask composition as claimed in claim 1, wherein:
R² is a substituted or unsubstituted C10 to C30 aromatic hydrocarbon ring group, and
the substituted or unsubstituted C10 to C30 aromatic hydrocarbon ring group includes a moiety of Group 2:

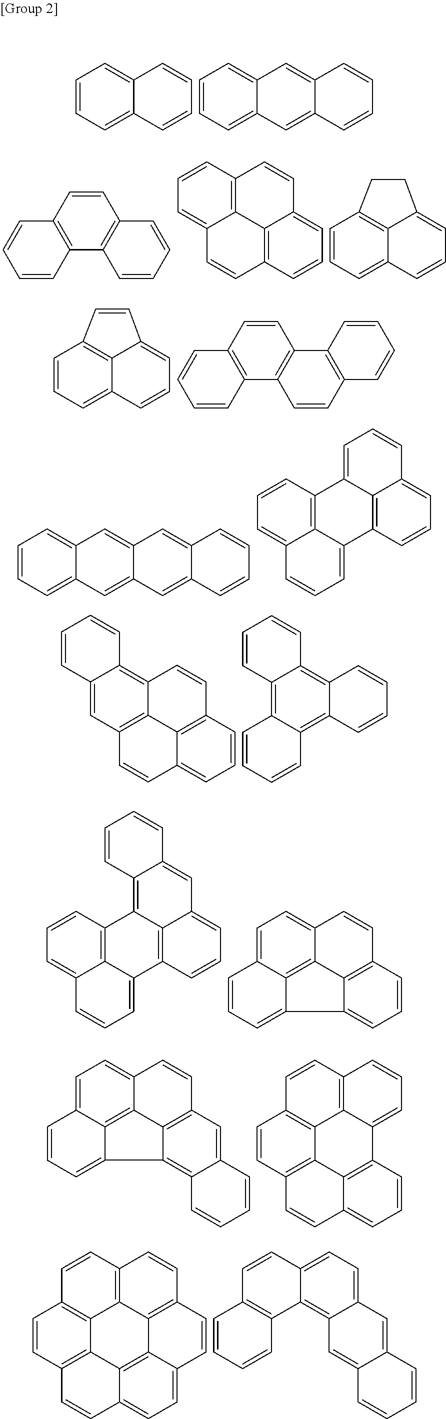

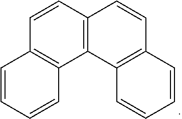 [SMILES: c1ccc2c(c1)ccc1ccc3ccccc3c12]

4. The hardmask composition as claimed in claim 1, wherein the substituted or unsubstituted C6 to C30 aromatic hydrocarbon ring group of R³ and R⁴ includes a moiety of Group 3:

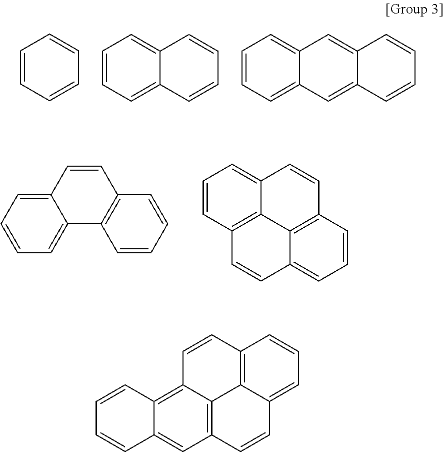

5. The hardmask composition as claimed in claim 1, wherein:
R² is a substituted or unsubstituted C10 to C30 aromatic hydrocarbon ring group, and
the substituted or unsubstituted C10 to C30 aromatic hydrocarbon ring group includes a moiety of Group 2-1:

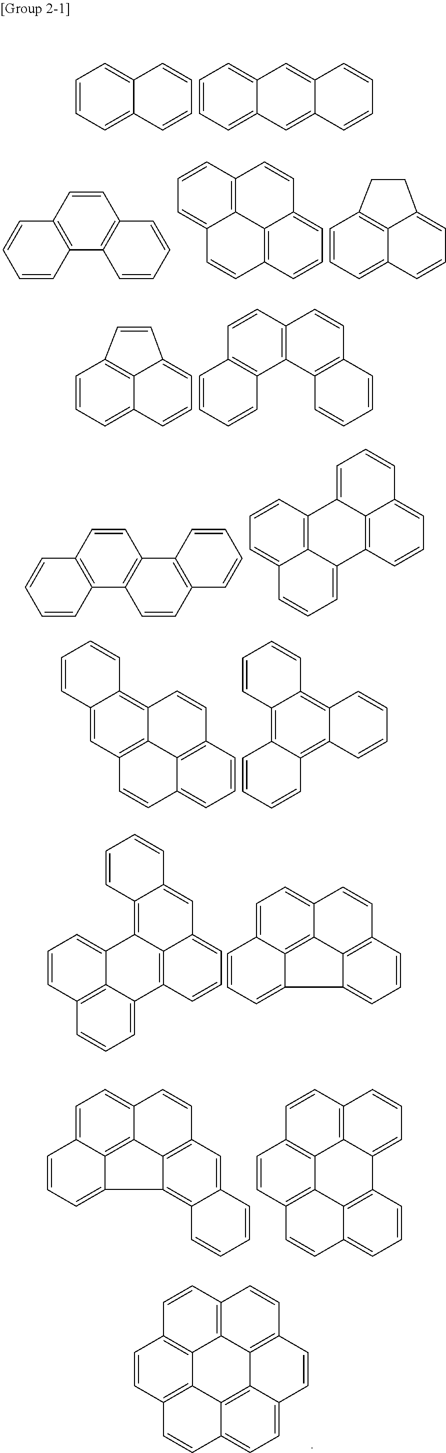

6. The hardmask composition as claimed in claim 1, wherein:
R¹ is a substituted or unsubstituted moiety of Group 1-2,
R² is a substituted or unsubstituted moiety of Group 2-2,
R³ and R⁴ are each independently a substituted or unsubstituted C6 to C24 aromatic hydrocarbon ring group, and
at least one of R¹ to R⁴ is substituted with a hydroxy group,

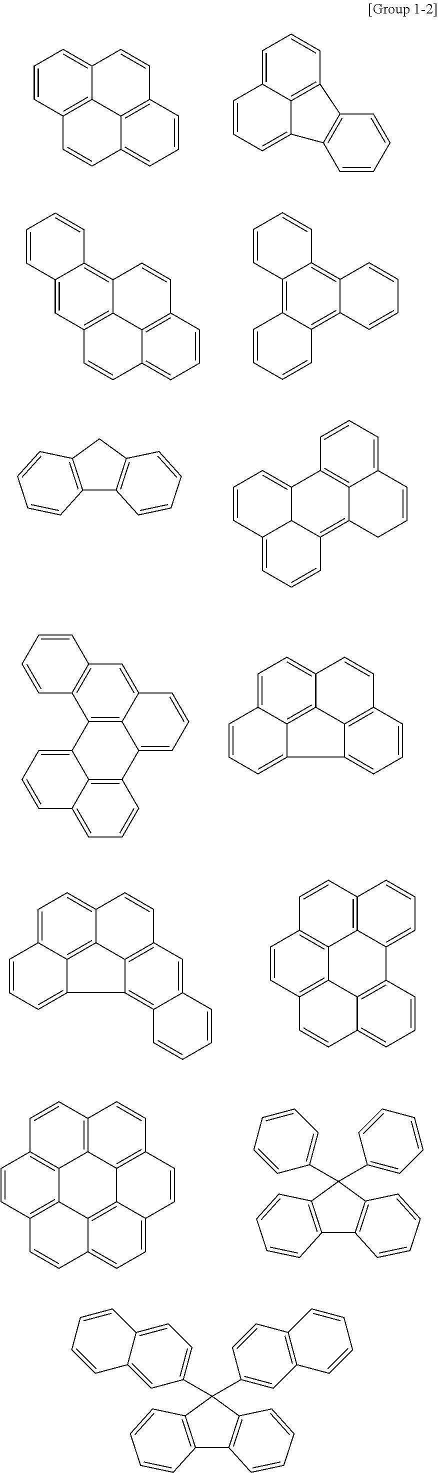

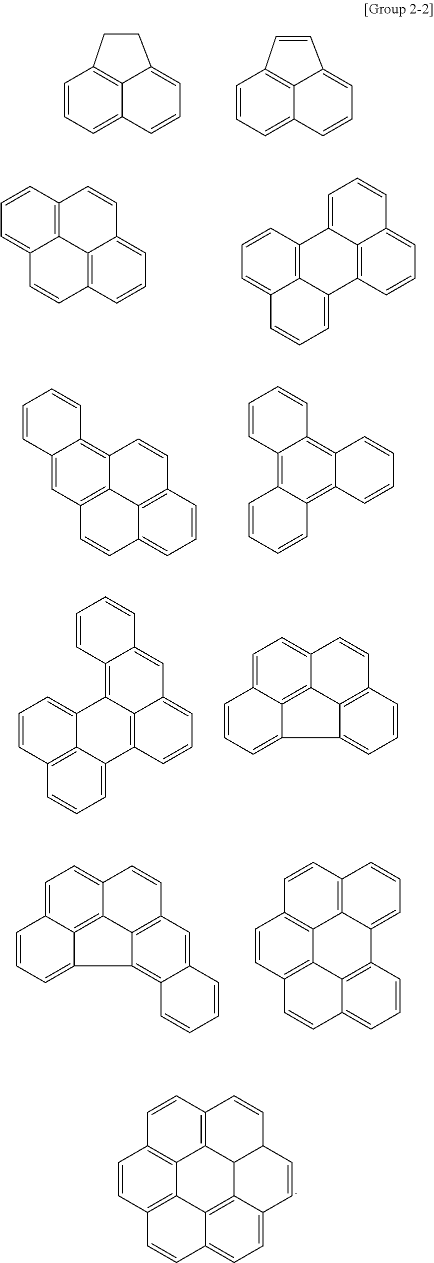

7. The hardmask composition as claimed in claim 6, wherein:
R¹ is a moiety of Group 1-2 that is substituted with one hydroxyl group, and
R² is a moiety of Group 2-2 that is substituted with one hydroxyl group.

8. The hardmask composition as claimed in claim 1, wherein:
the structural unit represented by Chemical Formula 1 is represented by Chemical Formula 2, 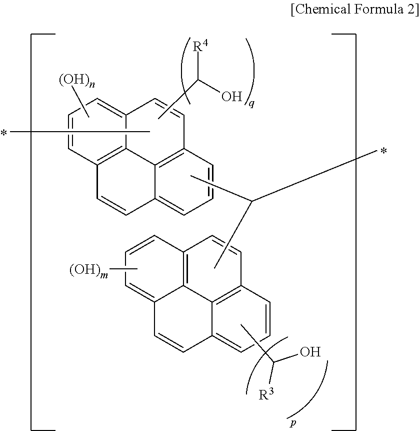
in Chemical Formula 2,
R³ and R⁴ are each independently a substituted or unsubstituted C6 to C30 aromatic hydrocarbon ring group,
p and q are each independently 0 or 1, and
n and m are each independently an integer of 0 to 8,
provided that, when both R³ and R⁴ are an unsubstituted C6 to C30 aromatic hydrocarbon ring group, n+m is not 0.

9. The hardmask composition as claimed in claim 1, wherein the structural unit represented by Chemical Formula 1 is represented by one of Chemical Formula 1-1 to Chemical Formula 1-8,

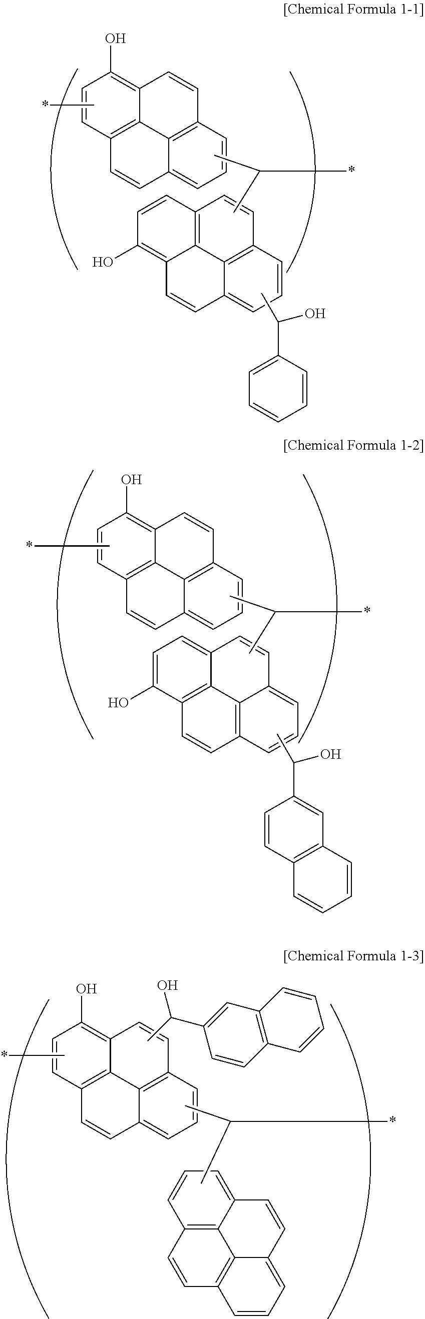

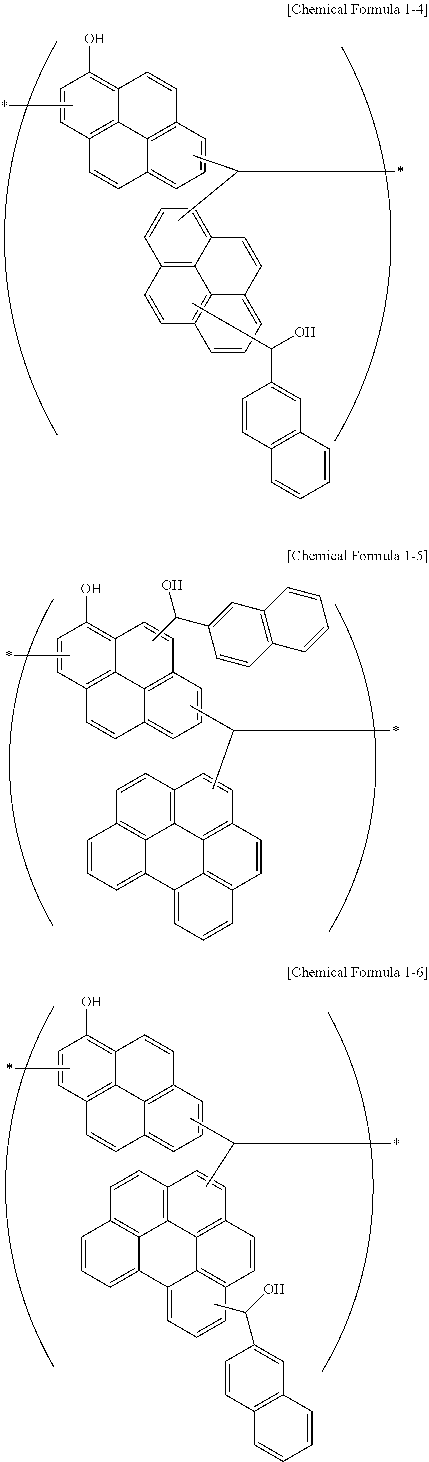

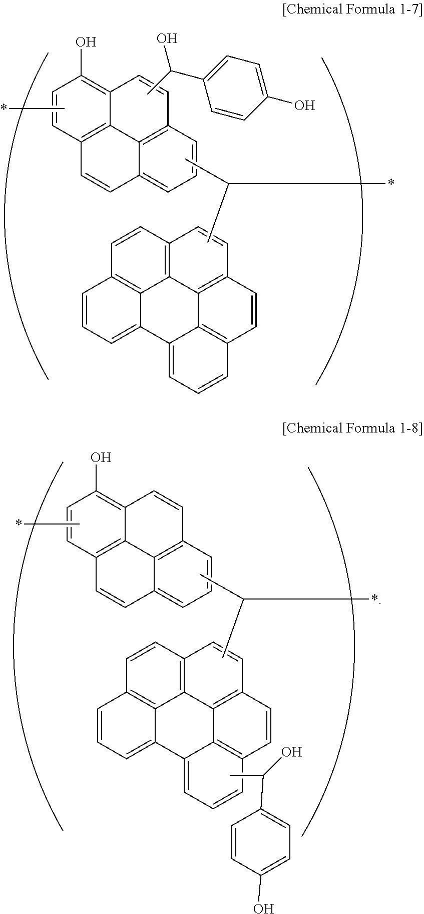

10. The hardmask composition as claimed in claim 1, wherein a weight average molecular weight of the polymer is about 1,000 g/mol to about 200,000 g/mol.

11. The hardmask composition as claimed in claim 1, wherein the polymer is included in an amount of about 0.1 wt % to about 30 wt %, based on a total weight of the hardmask composition.

12. The hardmask composition as claimed in claim 1, wherein the solvent includes propylene glycol, propylene glycol diacetate, methoxy propanediol, diethylene glycol, diethylene glycol butyl ether, tri(ethylene glycol)monomethyl ether, propylene glycol monomethyl ether, propylene glycol monomethyl ether acetate, cyclohexanone, ethyl lactate, gamma-butyrolactone, N,N-dimethyl formamide, N,N-dimethyl acetamide, methylpyrrolidone, methylpyrrolidinone, acetylacetone, or ethyl 3-ethoxypropionate.

13. A hardmask layer comprising a cured product of the hardmask composition as claimed in claim 1.

14. A method of forming patterns, the method comprising:
providing a material layer on a substrate,
applying the hardmask composition as claimed in claim 1 on the material layer,
heat-treating the hardmask composition to form a hardmask layer,
forming a photoresist layer on the hardmask layer,
exposing and developing the photoresist layer to form a photoresist pattern,
selectively removing the hardmask layer using the photoresist pattern to expose a portion of the material layer, and
etching an exposed part of the material layer.

15. The method as claimed in claim 14, wherein heat-treating the hardmask composition is performed at about 100° C. to about 1,000° C.
